(19) United States
(12) Patent Application Publication
(10) Pub. No.: US 2016/0276291 A1
(43) Pub. Date: Sep. 22, 2016

(54) SEMICONDUCTOR DEVICE AND MANUFACTURING METHOD OF SEMICONDUCTOR DEVICE

(71) Applicant: KABUSHIKI KAISHA TOSHIBA, Tokyo (JP)

(72) Inventor: Keisuke NAKAZAWA, Yokkaichi (JP)

(21) Appl. No.: 14/844,356

(22) Filed: Sep. 3, 2015

(30) Foreign Application Priority Data
Mar. 16, 2015 (JP) 2015-052710

(51) Int. Cl. H01L 23/00; H01L 23/31; H01L 21/02; H01L 23/29

(52) U.S. Cl. CPC H01L 23/562; H01L 23/291; H01L 23/3157; H01L 21/02164; H01L 21/02255

(57) ABSTRACT

According to one embodiment, a semiconductor device includes: a semiconductor substrate; and an insulating film provided above the semiconductor substrate. The insulating film includes: a plurality of first particles having a periodic structure; a plurality of second particles provided between the plurality of first particles and having an average particle outline size smaller than an average particle outline size of the plurality of first particles; and a filler provided between at least one of the plurality of first particles and the plurality of second particles.

### CROSS-REFERENCE TO RELATED APPLICATION

This application is based upon and claims the benefit of priority from Japanese Patent Application No. 2015-052710, filed on Mar. 16, 2015; the entire contents of which are incorporated herein by reference.

### FIELD

Embodiments described herein relate generally to a semiconductor device and a manufacturing method of semiconductor device.

### BACKGROUND

As an insulating film used for a semiconductor device, there is a case where, for example, an oxide film containing silicon dioxide is used. In a semiconductor device of MEMS (Micro Electro Mechanical Systems) or the like, an insulating film excellent in durability and having a thickness of several tens μm or more is required.

### BRIEF DESCRIPTION OF THE DRAWINGS

FIG. 1 is a schematic sectional view of an insulating film of a semiconductor device of an embodiment;

FIGS. 2A and 2B are schematic perspective views showing part of the configuration of the insulating film of the semiconductor device of the embodiment;

FIG. 3 is a schematic sectional view of the insulating film of a semiconductor device of the embodiment;

FIG. 4 is a flowchart of the manufacturing method of the insulating film of the semiconductor device of the embodiment; and

FIG. 5 to FIG. 11 are schematic sectional views showing the manufacturing method of the insulating film of the semiconductor device of the embodiment.

### DETAILED DESCRIPTION

According to one embodiment, a semiconductor device includes: a semiconductor substrate; and an insulating film provided above the semiconductor substrate. The insulating film includes: a plurality of first particles having a periodic structure; a plurality of second particles provided between the plurality of first particles and having an average particle outline size smaller than an average particle outline size of the plurality of first particles; and a filler provided between at least one of the plurality of first particles and the plurality of second particles.

Hereinafter, an embodiment will be described with reference to the drawings. Incidentally, the same components in the respective drawings are denoted by the same reference numerals.

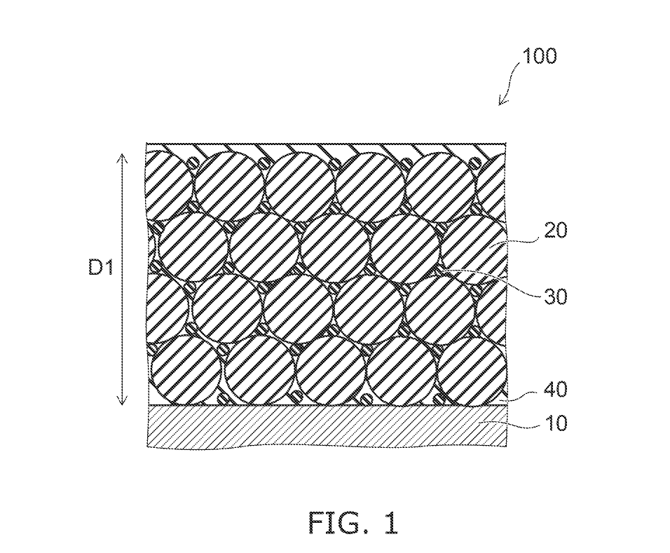

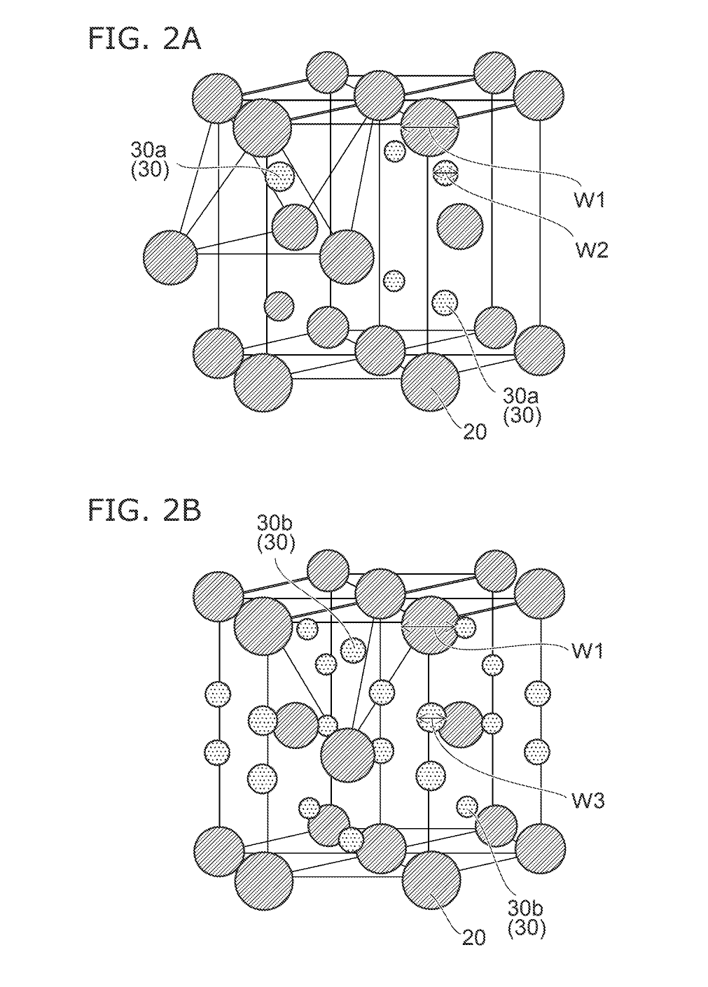

First, a configuration of an insulating film 100 of a semiconductor device of an embodiment will be described with reference to FIG. 1 to FIG. 2B.

FIG. 1 is a schematic sectional view of the insulating film 100 of the semiconductor device of the embodiment.

FIG. 2A and FIG. 2B are schematic perspective views showing part of the configuration of the insulating film 100 of the semiconductor device of the embodiment. Incidentally, in FIG. 2A and FIG. 2B, a filler 40 is omitted.

As shown in FIG. 1, the insulating film 100 is provided on a substrate 10. The insulating film 100 is provided around, for example, a not-shown conductor (conductive film) provided on the substrate 10.

A thickness D1 of the insulating film 100 is, for example, 10 micrometers (pm) or more. The thickness D1 of the insulating film 100 may be, for example, 1 micrometer or more. The insulating film 100 includes a plurality of first particles 20, a plurality of second particles 30 and a filler 40.

The plurality of first particles 20 has a periodic structure. The periodic structure of the plurality of first particles 20 is, for example, a hexagonal closest packing structure. The plurality of second particles 30 and the filler 40 are provided between the plurality of first particles 20.

The average particle outline size of the plurality of second particles 30 is smaller than the average particle outline size of the plurality of first particles 20. Thus, the plurality of second particles 30 is provided in the periodic structure (site) of the plurality of first particles 20.

The filler 40 is filled in spaces (gaps) between at least one of the plurality of first particles 20 and the plurality of second particles 30. The filler 40 covers, for example, peripheries of the plurality of first particles 20 and peripheries of the plurality of second particles 30. Incidentally, the foregoing gaps include spaces between the first particles 20, spaces between the second particles 30 and spaces between the first particles 20 and the second particles 30.

The plurality of first particles 20 and the plurality of second particles 30 contain an oxide, and contain, for example, silica (fumed silica, colloidal silica, fused silica, etc.). For example, the plurality of first particles 20 may contain material different from the plurality of second particles 30. The densities of the plurality of first particles 20 and the plurality of second particles 30 are desired to be high. At least one of the surfaces of the plurality of first particles 20 and the surfaces of the plurality of second particles 30 is terminated with oxygen or hydrogen. The plurality of first particles 20 and the plurality of second particles 30 have, for example, insulating properties.

The plurality of first particles 20 and the plurality of second particles 30 have, for example, a spherical shape or a true spherical shape. The particle diameter (outline size) distribution of the plurality of first particles 20 or the plurality of second particles 30 is such that, for example, with respect to the respective kinds of particles, a value in the particle diameter distribution obtained by dividing the standard deviation of the particle diameters by the average value of the particle diameters falls within a variation of 10% or less.

The filler 40 is an insulating material (oxide) derived from, for example, hydrogen silsesquioxane and perhydropolysilazane.

As shown in FIG. 2A and FIG. 2B, the plurality of second particles 30 is provided in the periodic structure of the plurality of first particles 20, for example, in the hexagonal closest packing structure. The plurality of second particles 30 includes first group particles 30a and second group particles 30b different from each other in average particle diameter. Incidentally, the respective particles 20 and 30 in FIG. 2A and FIG. 2B are shown using an average particle diameter W1 of the plurality of first particles 20 and an average particle diameter W2 of the plurality of second particles 30.

As shown in FIG. 2A, the first group particle 30a is surrounded by the six first particles 20 forming a regular octahedron. In this case, the number ratio of the first group particles 30a to the first particles 20 is 1. The average particle diameter W2 of the first group particles 30a is 0.42 or less times the average particle diameter W1 of the plurality of first particles 20.

As shown in FIG. 2B, the second group particle 30b is surrounded by the four first particles 20 forming a regular tetrahedron. In this case, the number ratio of the second group particles 30b to the first particles 20 is 2. An average particle diameter W3 of the second group particles 30b is 0.23 or less times the average particle diameter W1 of the plurality of first particles 20.

Incidentally, in the plurality of second particles 30, there is a case where the first group and the second group particles 30a and 30b are mixed at an arbitrary ratio and are used. At that time, the number ratio of the second particles 30 to the first particles 20 is 3.

The insulating film 100 includes a portion where the second particle does not exist between the plurality of first particles 20, and can include a portion where only the plurality of second particles 30 is provided. Besides, the arrangement of the plurality of first particles 20 may be shifted from the exact hexagonal closest packing structure, or a portion where there is no particle may exist, and a state resembling a crystal defect may occur.

In view of the above, in the insulating film 100, the number ratio of the plurality of second particles 30 to the plurality of first particles 20 is 0.2 or more and 10.0 or less, and is, for example, 0.4 or more and 4.0 or less.

Incidentally, the foregoing average particle diameters (average values of the particle diameters) of the particles indicate, for example, diameters corresponding to the respective peaks of the particle diameter distributions of the plurality of particles 20 and 30.

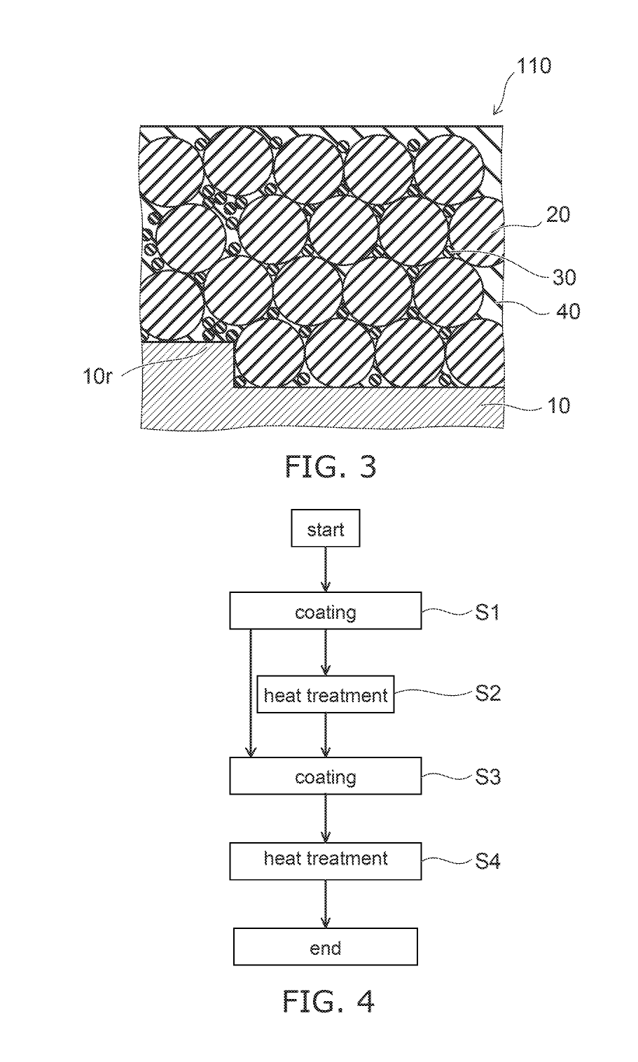

For example, as shown in FIG. 3, a step 10r is provided on the substrate 10 provided with an insulating film 110. At this time, the plurality of second particles 30 is gathered around the step 10r. Also in this case, the insulating film 110 includes a portion where the number ratio of the plurality of second particles 30 to the plurality of first particles 20 is 0.2 or more and 10 or less.

Incidentally, the step 10r of the substrate 10 includes, for example, a trench or a hole. When a distance between the trenches or the holes is smaller than the average particle diameter of the plurality of first particles 20, there is a case where the plurality of second particles 30 is provided between the trenches or the holes.

Next, a manufacturing method of the insulating film 100 of the semiconductor device of the embodiment will be described with reference to FIG. 4 to FIG. 7.

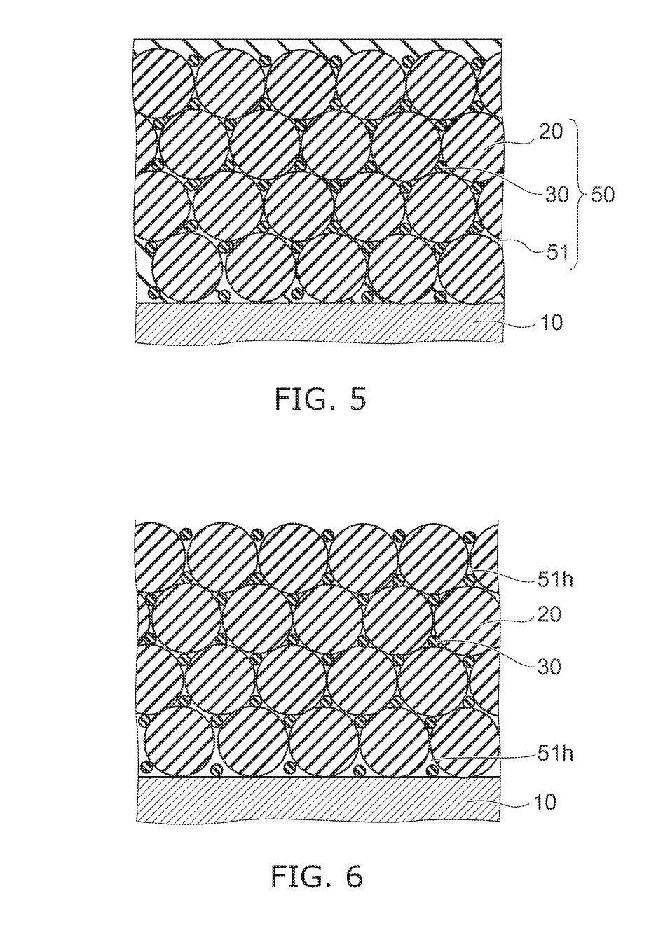

FIG. 4 is a flowchart of the manufacturing method of the insulating film 100 of the semiconductor device of the embodiment. FIG. 5 to FIG. 7 are schematic sectional views showing an example of the manufacturing method of the insulating film 100 of the semiconductor device of the embodiment.

At step S1, a first coating process is performed, and a film containing particles is formed. The step S1 includes a process of coating the substrate with a solution containing the particles, and a process of drying the substrate.

At step S2, a first heat treatment process is performed, and the intensity of the particle film is raised. Step S3 may be performed without performing step S2.

At step S3, a second coating process is performed, and a filler is made to flow into the spaces between the particles. The step S3 includes a process of coating the substrate with a solution containing the filler and a process of drying the substrate.

At step S4, a second heat treatment process is performed. The step S4 may include an oxidizing process or an annealing process. The annealing process may be performed after the oxidizing process is performed.

If the film thickness of the particles is insufficient, step S1 is repeated plural times to adjust the thickness to be suitable. Beside, the process from step S1 to step S2 may be repeated plural times.

If the amount of the filler is insufficient, step S3 is repeated plural times. Besides, the process from step S3 to step S4 may be repeated plural times.

As shown in FIG. 5, in the first coating process, a solution 50 (first solution) is supplied onto the substrate 10. The solution 50 contains a solvent 51 in which the plurality of first particles 20 and the plurality of second particles 30 are dispersed. As a method of supplying the solution 50, for example, a rotation coating method (spin coat method) is used. As the method of supplying the solution 50, a coating method other than the above may be used.

The solvent 51 contains, for example, an aqueous solvent (for example, water) or an organic solvent (for example, methyl ethyl ketone), and a material is selected according to the substrate 10 and surface states of the respective particles 20 and 30.

The substrate 10 includes, for example, a semiconductor substrate of MEMS or the like. For example, a trench or a hole of several tens μm may be formed on the substrate 10. The substrate 10 include, for example, a liquid crystal substrate.

The plurality of first particles 20 and the plurality of second particles 30 are dispersed in the solvent 51 at an arbitrary ratio and are supplied onto the substrate 10.

For example, the solvent 51 contains the first particles 20 (for example, silica particles) having an average particle diameter of 100 nm and the second particles 30 (for example, silica particles) having an average particle diameter of 40 nm, which are mixed at a ratio of 1:1. Besides, for example, the solvent 51 contains the first particles 20 having an average particle diameter of 100 nm and the second particles 30 having an average particle diameter of 20 nm, which are mixed at a ratio of 1:3. Besides, for example, the solvent 51 contains the first particles 20 (for example, silica particles) having an average particle diameter of 100 nm, the second particles 30a (for example, silica particles) having an average particle diameter of 40 nm and the second particles 30b (for example, silica particles) having an average particle diameter of 20 nm, which are mixed at a ratio of 1:1:3.

As shown in FIG. 3, for example, when the step 10r is provided on the substrate 10, the ratio of the particles is changed in view of the plurality of second particles 30 filled in the vicinity of the step 10r.

At this time, for example, the solvent 51 contains the first particles 20 having an average particle diameter of 100 nm and the second particles 30 having an average particle diameter of 40 nm, which are mixed at a ratio of 1:1.2. Besides, for example, the solvent 51 contains the first particles 20 having an average particle diameter of 100 nm and the second particles 30 having an average particle diameter of 20 nm, which are mixed at a ratio of 1:3.5.

Then, as shown in FIG. 6, the solvent 51 is removed by a heat treatment, and a gap 51h is formed. The heat treatment is performed at a temperature of, for example, 100° C. (for example, 80° C. or higher and 300° C. or lower), and the temperature is set according to the evaporation temperature of a material used as the solvent 51.

The plurality of first particles 20 on the substrate 10 is periodically arranged, and has, for example, a hexagonal closest packing structure. The plurality of first particles 20 may be periodically arranged when the solution 50 is supplied onto the substrate 10.

The plurality of second particles 20 on the substrate 10 is formed in the periodic structure of the plurality of first particles 20.

In the first heat treatment process, a higher temperature heat treatment is performed in addition to the above heat treatment, and the temperature is, for example, between 300° C. and 1000° C.

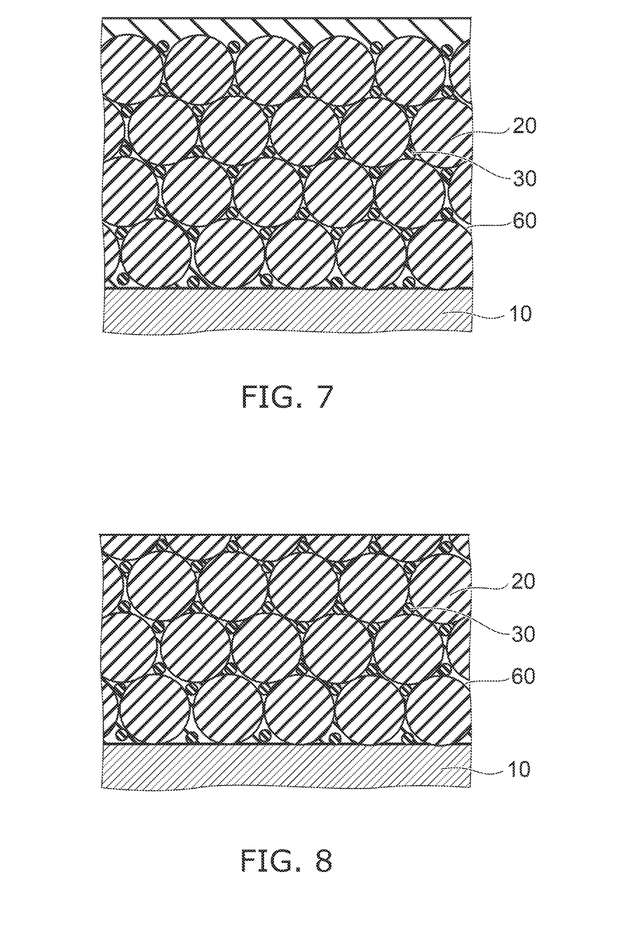

As shown in FIG. 7, in the second coating process, a solution 60 (second solution) containing a solvent and a molecule to be filled is coated between the plurality of first particles 20 and the plurality of second particles 30. The solution 60 is filled in the gap 51h. The molecule to be filled is, for example, hydrogen silsesquioxane or perhydropolysilazane.

The solvent of the solution 60 is removed by a heat treatment. The heat treatment is performed at a temperature of, for example, 100° C. (for example, 80° C. or higher and 300° C. or lower), and the temperature is set according to the evaporation temperature of a material used as the solvent.

In the second heat treatment process, the heat treatment is performed at a temperature between, for example, 300° C. and 1000° C. As an atmosphere in the heat treatment, an inert gas such as, for example, a nitrogen gas is used, or an oxidizing gas such as, for example, air or oxygen may be used. Besides, different gases are used, and the heat treatment may be performed plural times. The heat treatment may be performed simultaneously with the heat treatment for removing the solvent in the second coating process.

The second heat treatment is performed, so that hydrogen silsesquioxane or perhydropolysilazane, which is the filler, is transformed into silicon dioxide.

By this, the insulating film 100 shown in FIG. 1 is formed. The filler 40 is desired to be exposed on the upper surface of the particle layer.

Incidentally, the foregoing manufacturing method may be performed, for example, plural times, and the number of times thereof is arbitrary. Besides, for example, after the solution 60 is formed, a layer of only the filler is formed on the surface of the solution 60. This layer is removed by etching to expose a mixed layer of the respective particles 20 and 30 and the filler, and the solution 50 may be formed again in the exposed part.

After these processes, various films are further stacked, and processing is performed, so that the semiconductor device is manufactured. An example thereof will be described below.

As shown in FIG. 8, the filler 40 and the particle layer exposed on the surface are removed by using an etching method. The etching may be wet etching or dry etching. Besides, they may be removed by flattening using CMP (Chemical Mechanical Polish). Of course, this process may be omitted to proceed to a next process.

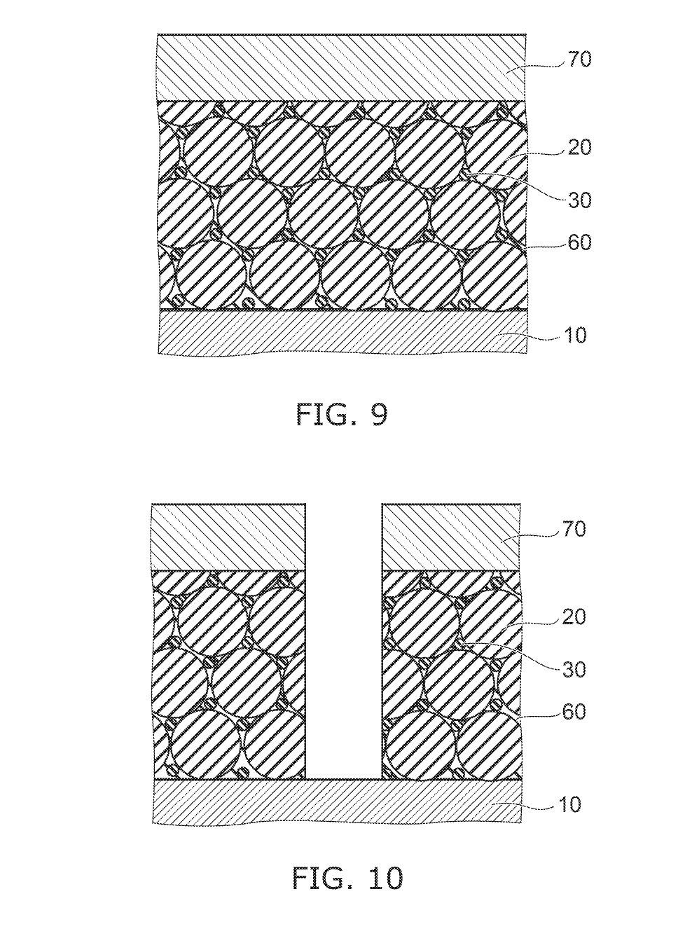

As an example, formation of a conductor will be described. For example, as shown in FIG. 9, a barrier film 70 of SiN or the like is formed.

Next, as shown in FIG. 10, processing is performed using lithography and a space is formed. For example, the space has a shape such as a trench or a hole.

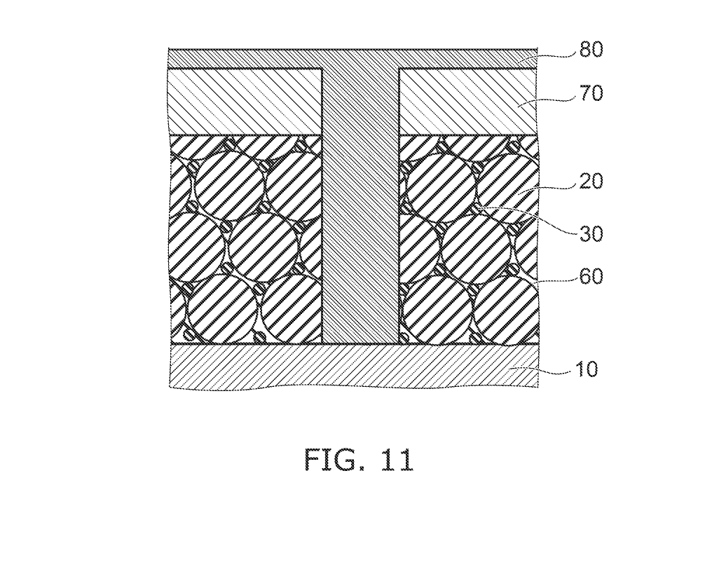

An intermediate 80 is embedded in the space (FIG. 11). Although a barrier layer is usually formed in the processed portion before the film formation of the intermediate 80, this is omitted in FIG. 11. The intermediate 80 includes, for example, a conductor of Cu or the like. In this case, the intermediate 80 may be used for the plug. The intermediate 80 may include, for example, an insulator. The intermediate 80 may include, for example, a plurality of layers. The intermediate 80 contacts, for example, the substrate 10. For example, the intermediate 80 may separate from the substrate 10.

Film formation, processing and the like are further performed and the semiconductor device is formed.

Next, effects of the embodiment will be described.

According to the embodiment, in the insulating film 100 of the semiconductor device, the plurality of second particles 30 and the filler 40 are provided between the plurality of first particles 20 having the periodic structure. By this, a gap between at least one of the plurality of first particles 20 and the plurality of second particles 30 can be filled, and the semiconductor device including the insulating film excellent in durability can be provided.

For example, if an insulating film made of only a filler (insulating material derived from perhydropolysilazane, hydrogen silsesquioxane, etc.) is formed, when the film thickness becomes 1 μm or more, a crack can occur. Besides, if an insulating film made of only the plurality of particles (silica particles) is formed, the density of the film becomes low and a crack is liable to occur.

On the other hand, according to the embodiment, the insulating film having high density can be formed, and occurrence of a crack can be suppressed. Besides, for example, the particle diameter distribution of the plurality of first particles 20 is such that the value obtained by dividing the standard deviation of the particle diameters by the average value falls within a variation of 10%. By this, the plurality of first particles 20 having the periodic structure in which a local dense-coarse difference is low can be formed. Thus, the insulating film having a higher density can be formed, and the occurrence of a crack can be suppressed. That is, the semiconductor device excellent in durability can be provided.

Further, the insulating film 100 of the embodiment is formed by the coating method excellent in flatness. By this, as compared with a film formation method such as an ALD method (atomic layer deposition) or a CVD method (chemical vapor deposition), the film can be formed in a short time.

When the film is formed on the step (trench etc.), if the CVD method is used, defective embedding (void) or the like can occur. On the other hand, according to the embodiment, the film can be formed without producing the defective embedding or the like also in the place having the step 10r. Further, also when only the film formed on the step 10r is removed, this can be easily performed. By this, the insulating film excellent in durability and having a thickness of several tens μm or more can be easily formed.

In addition to the above, according to the embodiment, after the plurality of first particles 20 and the plurality of second particles 30 (for example, silica particles) are formed, the filler 40 is formed.

As the forming method of the insulating film, there is a method of coating and firing a solution in which silica particles and polymer material or the like as the binder are mixed. The binder is filled between the silica particles, and the particles are prevented from coming in direct contact with each other and from forming a bond between the particles. Thus, the silica particles can not form a periodic structure. Besides, the ratio of the binder becomes large, and the volume of the binder after film formation becomes relatively large as compared with the volume of the particles. Thus, a crack due to the binder is liable to occur.

In general, polymer material containing an organic component is used as the binder. Since the organic component has a property to soften the structure, crack resistance is relatively high. However, the material can not resist a heat treatment at a high temperature. Although depend on a material, the upper limit of the binder based on siloxane polymer is about 600° C. In organic polymer material not containing silicon, the heat resistant temperature is much lower than this. When a heat treatment exceeding the heat resistant temperature is performed, such a problem occurs that an electric leak occurs by decomposition of the organic component, deformation of the semiconductor device occurs, or a void is formed in the film.

If inorganic material is used as the binder, although the decomposition of the organic component does not occur, since the volume of the binder is large as mentioned above, a crack is liable to occur.

On the other hand, in the forming method of the embodiment, the plurality of first particles 20 and the plurality of second particles 30 are in direct contact with each other between the particles. The filler 40 is filled therebetween. These particles can be connected without interruption from the substrate 10 to the upper particle outermost surface. Besides, the plurality of first particles 20 form the periodic structure, and the plurality of second particles 30 and the filler 40 are formed in the periodic structure. Thus, the filler 40 can be filled between the particles at the minimum volume. Thus, as compared with a case where the first particles 20 do not have the periodic structure, the insulating film having a high particle density per unit volume can be formed. When the silica particles are used, and the filler is made the oxide derived from hydrogen silsesquioxane or perhydropolysilazane, the absolute density can also be raised, and the semiconductor device including the insulating film excellent in durability can be formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a semiconductor substrate; and
an insulating film provided above the semiconductor substrate,
the insulating film including:
a plurality of first particles having a periodic structure;
a plurality of second particles provided between the plurality of first particles and having an average particle outline size smaller than an average particle outline size of the plurality of first particles; and
a filler provided between at least one of the plurality of first particles and the plurality of second particles.

2. The device according to claim 1, wherein the plurality of first particles contacts each other, and the plurality of first particles and the plurality of second particles contact each other.

3. The device according to claim 1, wherein the plurality of first particles has a hexagonal closest packing structure.

4. The device according to claim 1, wherein at least one of the plurality of first particles and the plurality of second particles contains silica.

5. The device according to claim 1, wherein the filler is an insulator derived from at least one of hydrogen silsesquioxane and perhydropolysilazane.

6. The device according to claim 1, wherein an average particle outline size of the plurality of second particles is 0.42 or less times an average particle outline size of the plurality of first particles.

7. The device according to claim 1, wherein an average particle outline size of the plurality of second particles is 0.23 or less times an average particle outline size of the plurality of first particles.

8. The device according to claim 1, wherein a number ratio of the plurality of second particles to the plurality of first particles is 0.2 or more and 10.0 or less.

9. The device according to claim 1, wherein a number ratio of the plurality of second particles to the plurality of first particles is 0.4 or more and 4.0 or less.

10. The device according to claim 1, wherein at least one of the first particles and the second particles has a spherical shape.

11. The device according to claim 1, wherein at least one of the plurality of first particles and the plurality of second particles has a particle outline size distribution, a value in the particle outline size distribution obtained by dividing a standard deviation of particle outline size by an average value of the particle outline size is 10% or less.

12. The device according to claim 1, wherein the plurality of first particles contains a material different from the plurality of second particles.

13. The device according to claim 1, wherein a thickness of the insulating film is 10 micrometers or more.

14. The device according to claim 1, wherein the filler covers peripheries of the plurality of first particles and the plurality of second particles.

15. The device according to claim 1, wherein at least one of the plurality of first particles and the plurality of second particles contains at least one of fumed silica, colloidal silica and fused silica.

16. The device according to claim 1, wherein at least one of the plurality of first particles and the plurality of second particles is terminated with oxygen or hydrogen.

17. The device according to claim 1, wherein the insulating film is provided on the semiconductor substrate including a step.

18. The device according to claim 1, further comprising an intermediate provided in the insulating film.

19. A manufacturing method of a semiconductor device, comprising:
supplying a first solution onto a substrate and containing:
a plurality of first particles;
a plurality of second particles having an average particle outline size smaller than an average particle outline size of the plurality of first particles; and
a solvent dispersed with the plurality of first particles and the plurality of second particles;
arranging the plurality of first particles periodically by removing the solvent; and
supplying a second solution containing a filler into a gap formed by removing the solvent.

20. The method according to claim 19, wherein the arranging the plurality of first particles periodically includes arranging the plurality of first particles in a hexagonal closest packing structure.
